(19) United States
(12) Patent Application Publication
(10) Pub. No.: US 2017/0125570 A1
(43) Pub. Date: May 4, 2017

(54) COMPOUND SEMICONDUCTOR DEVICE AND METHOD OF MANUFACTURING THE SAME

(71) Applicant: FUJITSU LIMITED, Kawasaki-shi (JP)

(72) Inventors: Kozo Makiyama, Kawasaki (JP); Yuichi Minoura, Machida (JP); Shirou OZAKI, Yamato (JP)

(73) Assignee: FUJITSU LIMITED, Kawasaki-shi (JP)

(21) Appl. No.: 15/332,667

(22) Filed: Oct. 24, 2016

(30) Foreign Application Priority Data
Oct. 30, 2015 (JP) 2015-214953

(51) Int. Cl. H01L 29/778; H01L 21/306; H01L 21/308; H01L 29/66; H01L 29/40

(52) U.S. Cl. CPC H01L 29/7787; H01L 29/66462; H01L 29/401; H01L 21/308; H01L 21/30612

(57) ABSTRACT

A compound semiconductor device includes a compound semiconductor layer including an electron transit layer and an electron supply layer above the electron transit layer, the electron supply layer including a first layer including InAlN and a second layer including InAlGaN formed above the first layer.

### CROSS-REFERENCE TO RELATED APPLICATION

This application is based upon and claims the benefit of priority of the prior Japanese Patent Application No. 2015-214953, filed on Oct. 30, 2015, the entire contents of which are incorporated herein by reference.

### FIELD

The embodiments discussed herein are directed to a compound semiconductor device and a method of manufacturing the same.

### BACKGROUND

In a compound semiconductor device, in particular, a super-high frequency device using a GaN-HEMT, an electron supply layer composed of an In-based nitride semiconductor such as InAlN having high spontaneous polarization can be used in place of a conventional electron supply layer composed of AlGaN in order to realize its higher output. The electron supply layer composed of an In-based nitride semiconductor can induce a two-dimensional electron gas with high concentration even if it is a thin film, and therefore attracts attention as a material having both high output performance and high frequency performance.

[Patent Document 1] Japanese Laid-open Patent Publication No. 2011-49461

[Patent Document 2] International Publication Pamphlet No. WO2012/014883

### SUMMARY

The nitride semiconductor represented by InAlN has difficulty in crystal growth and is thus apt to cause a condensation phenomenon of In as illustrated in FIG. 26. An In condensation point formed by the condensation phenomenon causes a gate leakage current when the In condensation point coincides with a gate electrode forming region. As compared with a general AlGaN/GaN-HEMT, an increase in leakage current of at least two digits or more is observed in the InAlN/GaN-HEMT. The gate leakage causes a decrease in output property and a decrease in reliability of an amplifier. Further, InAlN having an In composition of 17% lattice matching with a general GaN channel has an Al composition reaching 83%, and thus has a problem of a current collapse being apt to occur due to an Al oxide.

One aspect of a compound semiconductor device includes a compound semiconductor layer including an electron transit layer and an electron supply layer above the electron transit layer, the electron supply layer including: a first layer including InAlN; and a second layer including InAlGaN formed above the first layer.

One aspect of a method of manufacturing a compound semiconductor device includes: when forming a compound semiconductor layer, forming an electron transit layer; and forming an electron supply layer above the electron transit layer, the electron supply layer including: a first layer including InAlN; and a second layer including InAlGaN formed above the first layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1E are schematic cross-sectional views illustrating a method of manufacturing an InAlGaN/InAlN/GaN•HEMT according to a first embodiment in order of processes;

FIGS. 2A to 2C are schematic cross-sectional views subsequent to FIGS. 1A to 1E, illustrating the method of manufacturing the InAlGaN/InAlN/GaN•HEMT according to the first embodiment in order of processes;

FIGS. 3A to 3C are schematic cross-sectional views subsequent to FIGS. 2A to 2C, illustrating the method of manufacturing the InAlGaN/InAlN/GaN•HEMT according to the first embodiment in order of processes;

FIG. 4 is a characteristic diagram illustrating gate two-terminal reverse leakage characteristics in the InAlGaN/InAlN/GaN•HEMT fabricated using the first embodiment on the basis of comparison with a comparative example;

FIGS. 5A and 5B are characteristic diagrams illustrating three-terminal characteristics in the InAlGaN/InAlN/GaN•HEMT fabricated using the first embodiment on the basis of comparison with the comparative example;

FIGS. 6A to 6C are characteristic diagrams illustrating a band structure in the InAlGaN/InAlN/GaN•HEMT fabricated using the first embodiment on the basis of comparison with the comparative example;

FIG. 7 is a schematic view defining A-B in a thickness direction of a compound semiconductor layer;

FIG. 8A to FIG. 8E are schematic cross-sectional views illustrating a method of manufacturing an InAlGaN/InAlN/GaN•HEMT according to a second embodiment in order of processes;

FIGS. 9A to 9C are schematic cross-sectional views subsequent to FIGS. 8A to 8E, illustrating the method of manufacturing the InAlGaN/InAlN/GaN•HEMT according to the second embodiment in order of processes;

FIGS. 10A to 10C are schematic cross-sectional views subsequent to FIGS. 9A to 9C, illustrating the method of manufacturing the InAlGaN/InAlN/GaN•HEMT according to the second embodiment in order of processes;

FIG. 11 is a characteristic diagram illustrating gate two-terminal reverse leakage characteristics in the InAlGaN/InAlN/GaN•HEMT fabricated using the second embodiment on the basis of comparison with a comparative example;

FIGS. 12A and 12B are characteristic diagrams illustrating three-terminal characteristics in the InAlGaN/InAlN/GaN•HEMT fabricated using the second embodiment on the basis of comparison with the comparative example;

FIG. 13A to FIG. 13E are schematic cross-sectional views illustrating a method of manufacturing an InAlGaN/InAlN/GaN•HEMT according to a third embodiment in order of processes;

FIGS. 14A to 14C are schematic cross-sectional views subsequent to FIGS. 13A to 13E, illustrating the method of manufacturing the InAlGaN/InAlN/GaN•HEMT according to the third embodiment in order of processes;

FIGS. 15A to 15C are schematic cross-sectional views subsequent to FIGS. 14A to 14C, illustrating the method of manufacturing the InAlGaN/InAlN/GaN•HEMT according to the third embodiment in order of processes;

FIG. 16 is a characteristic diagram illustrating gate two-terminal reverse leakage characteristics in the InAlGaN/InAlN/GaN•HEMT fabricated using the third embodiment on the basis of comparison with a comparative example;

FIGS. 17A and 17B are characteristic diagrams illustrating three-terminal characteristics in the InAlGaN/InAlN/GaN•HEMT fabricated using the third embodiment on the basis of comparison with the comparative example;

FIG. 18A to FIG. 18E are schematic cross-sectional views illustrating a method of manufacturing an InAlGaN/InAlN/GaN•HEMT according to a fourth embodiment in order of processes;

FIGS. 19A to 19C are schematic cross-sectional views subsequent to FIGS. 18A to 18E, illustrating the method of manufacturing the InAlGaN/InAlN/GaN•HEMT according to the fourth embodiment in order of processes;

FIGS. 20A to 20C are schematic cross-sectional views subsequent to FIGS. 19A to 19C, illustrating the method of manufacturing the InAlGaN/InAlN/GaN•HEMT according to the fourth embodiment in order of processes;

FIG. 21 is a schematic cross-sectional view illustrating a process of forming fine pits in a first electron supply layer in a film thickness direction thereof;

FIG. 22 is a characteristic diagram illustrating gate two-terminal reverse leakage characteristics in the InAlGaN/InAlN/GaN•HEMT fabricated using the fourth embodiment on the basis of comparison with a comparative example;

FIGS. 23A and 23B are characteristic diagrams illustrating three-terminal characteristics in the InAlGaN/InAlN/GaN•HEMT fabricated using the fourth embodiment on the basis of comparison with the comparative example;

FIG. 24 is a connection diagram illustrating a schematic configuration of a power supply device according to a fifth embodiment;

FIG. 25 is a connection diagram illustrating a schematic configuration of a high-frequency amplifier according to a sixth embodiment; and

FIG. 26 is a schematic view illustrating a state of a surface of an InAlN layer on which an In condensation point is formed.

### DESCRIPTION OF EMBODIMENTS

Hereinafter, various embodiments will be described in detail referring to the drawings. In the following embodiments, the configuration of a compound semiconductor device will be described along with its manufacturing method.

Note that in the following drawings, some components are not illustrated in accurate relative size and thickness for convenience.

### First Embodiment

In this embodiment, a Schottky-type InAlGaN/InAlN/GaN•HEMT is disclosed as a compound semiconductor device.

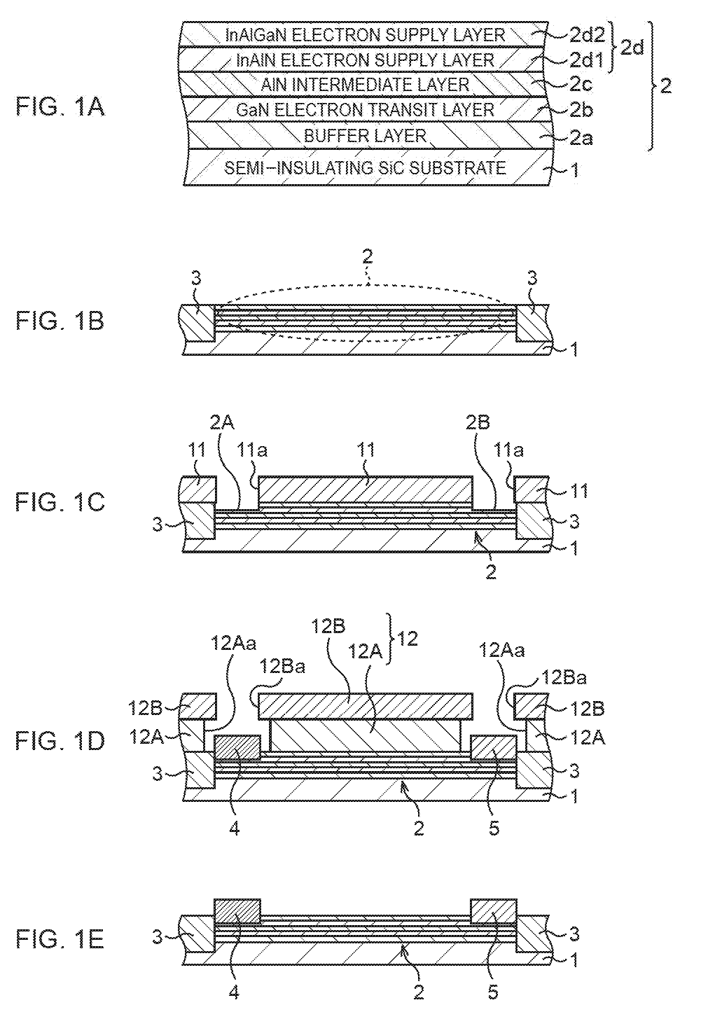

FIG. 1A to FIG. 3C are schematic cross-sectional views illustrating a method of manufacturing the Schottky-type InAlGaN/InAlN/GaN•HEMT according to a first embodiment in order of processes.

First, as illustrated in FIG. 1A, a compound semiconductor layer 2 being a layered structure of compound semiconductors is formed on, for example, a semi-insulating SiC substrate 1 as a growth substrate.

As the growth substrate, a Si substrate, a sapphire substrate, a GaAs substrate, a GaN substrate, or the like may be used in place of the SiC substrate. Further, the conductivity of the substrate may be either semi-insulating or conductive.

The compound semiconductor layer 2 is composed of a buffer layer 2a, an electron transit layer 2b, an intermediate layer 2c, and an electron supply layer 2d. The electron transit layer 2b includes GaN. The intermediate layer 2c includes, for example, AlN. In place of AlN, GaN may be used. The electron supply layer 2d is composed of a first electron supply layer 2d1 including InAlN, and a second electron supply layer 2d2 including InAlGaN formed on the first electron supply layer 2d1. In the InAlGaN/InAlN•HEMT, a two-dimensional electron gas (2DEG) is generated in the vicinity of an interface of the electron transit layer 2b with the electron supply layer 2d (precisely, the intermediate layer 2c). Note that formation of the intermediate layer 2c may be omitted.

More specifically, each compound semiconductor below is grown by, for example, a metal organic vapor phase epitaxy (MOVPE) method on the SiC substrate 1. A molecular beam epitaxy (MBE) method or the like may be used in place of the MOVPE method.

On the SiC substrate 1, AlN, (intentionally undoped) —GaN, AlN, InAlN and InAlGaN are deposited in sequence. The buffer layer 2a is formed of AlN or the like. The electron transit layer 2b is formed of i-GaN. The intermediate layer 2c is formed of AlN. The first electron supply layer 2d1 is formed of InAlN, for example, In_{0.17}AlN. The second electron supply layer 2d2 is formed of InAlGaN to be made relatively lower in In composition than InAlN of the first electron supply layer 2d1 by containing Ga, for example, an In composition of 5% or less.

A growth condition of AlN, GaN, InAlN, InAlGaN is use of, as a material gas, a mixed gas of a trimethylaluminum gas, a trimethylgallium gas, a trimethylindium gas, and an ammonia gas. Presence and absence of supply and flow rates of the trimethylaluminum gas being an Al source, the trimethylgallium gas being a Ga source, the trimethylindium gas being an In source are appropriately set in accordance with the compound semiconductor layer to be grown. The flow rate of the ammonia gas being a common material is set to about 100 sccm to 10 LM. Besides, the growth pressure is set to about 50 Torr to 300 Torr, and the growth temperature is set to about 600° C. to 1200° C.

The buffer layer 2a is formed into a film thickness of about 0.1 μm, the electron transit layer 2b is formed into a film thickness of about 3 μm, and the intermediate layer 2c is formed into a film thickness of about 1 nm. The first electron supply layer 2d1 is formed into a film thickness of about 5 nm and an In rate of 0.17, and the second electron supply layer 2d2 is formed into a film thickness of about 5 nm and an In rate of, for example, about 3% to about 10% lower than that of the first electron supply layer 2d1.

Subsequently, as illustrated in FIG. 1B, element isolation structures 3 are formed.

More specifically, for example, argon (Ar) is injected into element isolation regions of the compound semiconductor layer 2. The element isolation structures 3 are thereby formed in the compound semiconductor layer 2 and a surface layer part of the SiC substrate 1. Active regions are demarcated on the compound semiconductor layer 2 by the element isolation structures 3.

Note that the element isolation may be performed by using, for example, an STI (Shallow Trench Isolation) method in place of the above-described injection method.

Subsequently, as illustrated in FIG. 1C, electrode trenches 2A, 2B are formed in a part of the first electron supply layer 2d1 and in the second electron supply layer 2d2 at planned electrode formation positions for a source electrode and a drain electrode in the surface of the compound semiconductor layer 2.

A resist is applied to the surface of the compound semiconductor layer 2 and processed by lithography. Thereby, a resist mask 11 having openings 11a exposing the planned electrode formation positions for the source electrode and the drain electrode in the surface of the compound semiconductor layer 2 is formed. Dry etching using the resist mask 11 is performed penetrating the second electron supply layer 2d2 down to a part of the first electron supply layer 2d1. This forms the electrode trenches 2A, 2B. For the dry etching, an inert gas such as Ar and a chlorine-based gas such as Cl₂ are used as an etching gas. Here, the dry etching may be performed penetrating the second electron supply layer 2d2 and the first electron supply layer 2d1 down to a surface layer part of the electron transit layer 2b to thereby form the electrode trenches.

The resist mask 11 is removed by ashing using oxygen plasma or by wet treatment using a chemical.

Subsequently, as illustrated in FIGS. 1D, 1E, a source electrode 4 and a drain electrode 5 are formed.

As an electrode material, for example, Ti/Al is used. For formation of the electrodes, for example, an eaves-structure two-layer resist mask 12 suitable for a vapor deposition method and a lift-off method is formed. The resist mask 12 is composed of a lower layer resist 12A having openings 12Aa and an upper layer resist 12Ba having openings 12Ba. The electrode trench 2A is exposed from one of the openings 12Ba, and the electrode trench 2B is exposed from the other of the openings 12Ba. Using this resist mask 12, Ti/Al is deposited. The thickness of Ti is set to about 20 nm, and the thickness of Al is set to about 200 nm. By the lift-off method, the resist mask 12 and Ti/Al deposited thereon (illustration thereof is omitted in FIG. 1D) are removed. Thereafter, the SiC substrate 1 is heat treated at about 550° C., for example, in a nitrogen atmosphere, and remaining Ti/Al is brought into ohmic contact with the electron supply layer 2d. Thereby, the source electrode 4 and the drain electrode 5 are formed which are made by embedding lower parts of Ti/Al in the electrode trenches 2A, 2B.

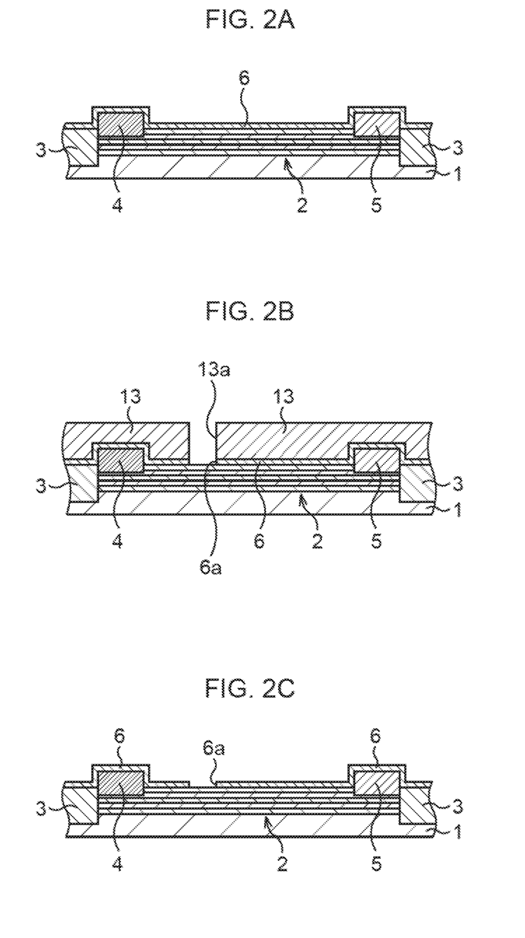

Subsequently, as illustrated in FIG. 2A, a protective insulating film 6 is formed.

More specifically, an insulating material, for example, a silicon nitride (SiN) is deposited on the entire compound semiconductor layer 2 to a thickness of, for example, about 50 nm using a plasma CVD method or the like. Thus, the protective insulating film 6 is formed. For the formation of the protective insulating film 6, for example, silane (SiH₄) is used as a Si material and ammonia (NH₃) is used as an N material. In the protective insulating film 6, a refractive index to light of a wavelength of 633 nm nearly corresponds to a stoichiometry of 2.0.

Subsequently, as illustrated in FIG. 2B, a trench 6a is formed in the protective insulating film 6.

More specifically, first, a resist is applied to the entire surface of the protective insulating film 6, for example, by the spin coating method. As the resist, for example, brand name PMMA manufactured by MicroChem Corp. being an electron beam resist is used. The applied resist is exposed to light by applying an electron beam of a length of 0.1 μm in a current direction thereon, and then developed. Thereby, a resist mask 13 having an opening 13a is formed.

Next, using the resist mask 13, dry etching is performed on the protective insulating film 6 until the surface of the second electron supply layer 2d2 is exposed at a bottom of the opening 13a. For the etching gas, for example, SF₆ is used. Thereby, the trench 6a being a through trench having a width of about 100 nm and exposing the surface of a cap layer 2d2 is formed in the protective insulating film 6.

Subsequently, as illustrated in FIG. 2C, the resist mask 13 is removed by ashing using oxygen plasma or by wet treatment using a chemical.

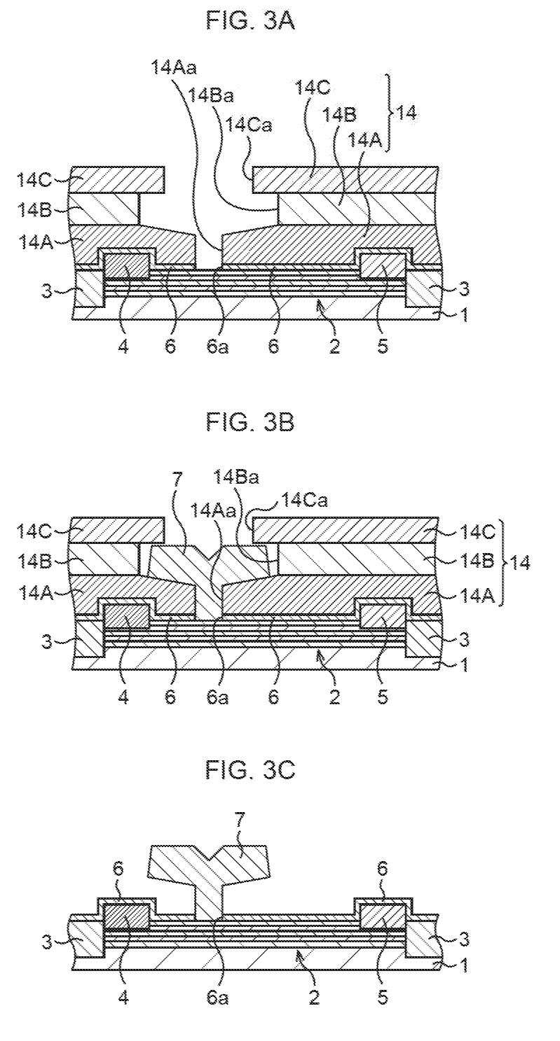

Subsequently, as illustrated in FIG. 3A, a resist mask 14 for formation of a gate is formed.

More specifically, first, a lower layer resist 14A (for example, brand name PMMA: manufactured by MicroChem Corp., USA), an intermediate layer resist 14B (for example, brand name PMGI: manufactured by MicroChem Corp., USA), and an upper layer resist 14C (for example, brand name: ZEP520: ZEON CORPORATION) are each applied and formed on the entire surface by the spin coating method. A gate forming region of the upper layer resist 14C is exposed to light by making an electron beam of a length of 0.8 μm in a current direction incident thereon. After the electron beam lithography, an opening 14Ca having a length of 0.8 μm is formed in the upper layer resist 14C using a developing solution (for example, brand name: ZEP-SD manufactured by ZEON CORPORATION). Next, the intermediate layer resist 14B in a region that is set back by about 0.5 μm in an ohmic electrode direction from an opening end of the upper layer resist 14C is removed using a developing solution (for example, brand name: NMD-W manufactured by Tokyo Ohka Kogyo Co., Ltd.) to form an opening 14Ba in the intermediate layer resist 14B. Next, middle portions of the opening 14Ca of the upper layer resist 14C and the opening 14Ba of the intermediate layer resist 14B are exposed to light by making an electron beam of a length of 100 nm in a current direction incident thereon in a manner to coincide with the trench 6a of the protective insulating film 6. After the electron beam lithography, an opening 14Aa having a length of 100 nm is formed in the lower layer resist 14A using a developing solution (for example, brand name: ZMD-B manufactured by Tokyo Ohka Kogyo Co., Ltd.).

Subsequently, as illustrated in FIG. 3B, a gate electrode 7 is formed.

More specifically, Ni is vapor-deposited into a thickness of about 10 nm and Au is successively vapor-deposited into a thickness of about 300 nm as a gate metal in the openings 14Aa, 14Ba, 14Ca using the resist mask 14. Illustration of the gate metal deposited on the resist mask 14 is omitted. Thus, the gate electrode 7 is formed.

Subsequently, as illustrated in FIG. 3C, the resist mask 14 is removed.

More specifically, the SiC substrate 1 is immersed in N-methyl-pyrrolidinone warmed to 80° C., and the resist mask 14 and unnecessary gate metal are removed by the lift-off method.

Thereafter, through processes such as electrical connection and so on of the source electrode 4, the drain electrode 5, and the gate electrode 7, the InAlGaN/InAlN/GaN•HEMT according to this embodiment is formed.

Generation of an In condensation point of InAlN is caused by the difference in growth conditions between InN and AlN. In the case of the MOVPE method used for forming an InAlN crystal, the film-forming temperatures, the gas mixture ratios and so on of InN and AlN are completely opposite in growth conditions. Inevitably, a window of the film-forming conditions of InAlN being a mixed crystal of them is extremely small and likely to cause an In condensation point and the like.

In this embodiment, the electron supply layer 2d of the compound semiconductor layer 2 is formed in a two-layer structure having the first electron supply layer 2d1 of InAlN on the rear surface side (the electron transit layer 2b side) and the second electron supply layer 2d2 of InAlGaN on the front surface side. InAlN of the first electron supply layer 2d1 on the rear surface side can generate high spontaneous polarization electric charges with a relatively low In composition. Further, InAlN has a feature of being likely to cause crystal defects such as an In condensation and the like as the film-forming technique. Therefore, it is impossible to achieve both a large current density by a high polarization density and a low gate leakage current. Furthermore, InAlGaN of the second electron supply layer 2d2 on the front surface side is lower in Al composition on the front surface than InAlN of the first electron supply layer 2d1, and therefor can reduce the current collapse caused by an Al oxide.

Hereinafter, operations and effects exhibited by the InAlGaN/InAlN/GaN•HEMT according to this embodiment will be described based on comparison with a comparative example.

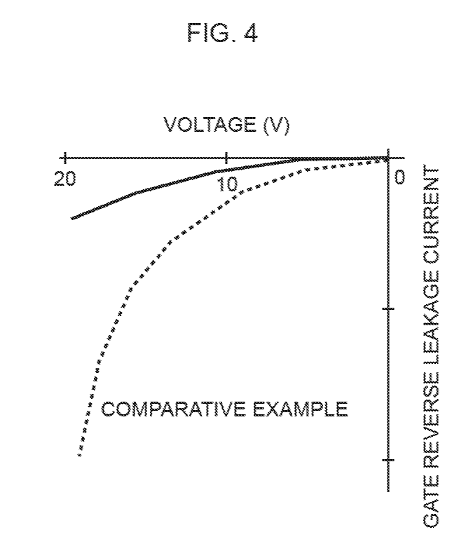

FIG. 4 is a characteristic diagram illustrating gate two-terminal reverse leakage characteristics in the InAlGaN/InAlN/GaN•HEMT fabricated using this embodiment on the basis of comparison with the comparative example. In the diagram, a solid line indicates this embodiment, and a broken line indicates the comparative example.

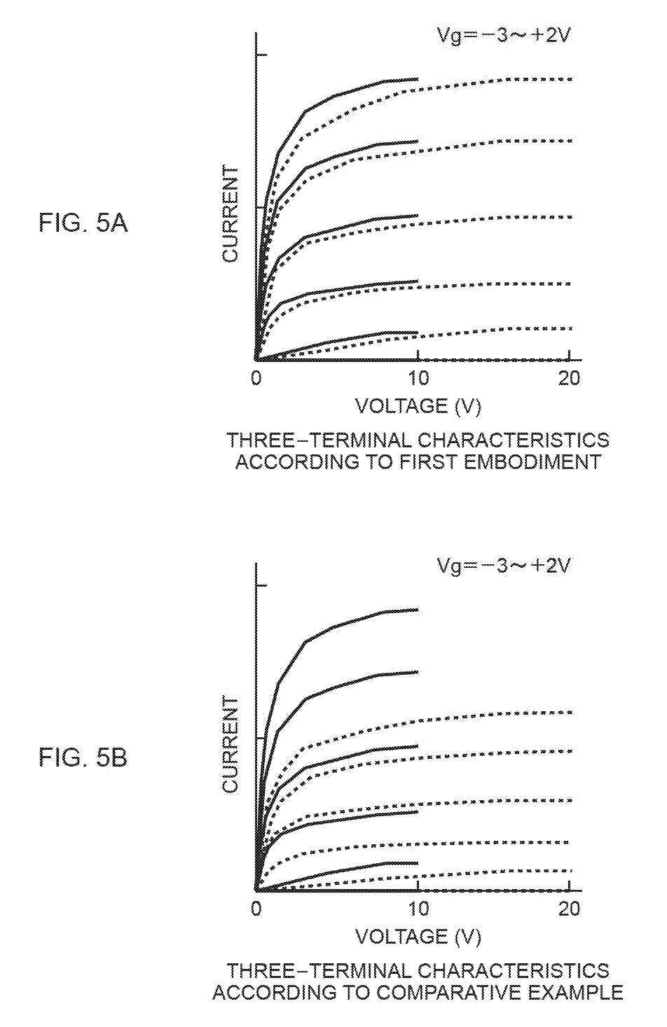

FIGS. 5A and 5B are characteristic diagrams illustrating three-terminal characteristics in the InAlGaN/InAlN/GaN•HEMT fabricated using this embodiment on the basis of comparison with the comparative example. FIG. 5A indicates this embodiment, and FIG. 5B indicates the comparative example. In the diagram, solid lines indicate low-bias stress states, and broken lines indicate high-bias stress states.

The comparative example is a so-called InAlN/GaN•HEMT having an electron supply layer in a single-layer structure of InAlN.

It has been confirmed from the measurement results in FIG. 4 and FIGS. 5A and 5B that a large gate leakage current flows in the comparative example, whereas the gate leakage current is greatly reduced in this embodiment as compared with the comparative example. Further, an effect of reducing the current collapse by this embodiment has also been confirmed.

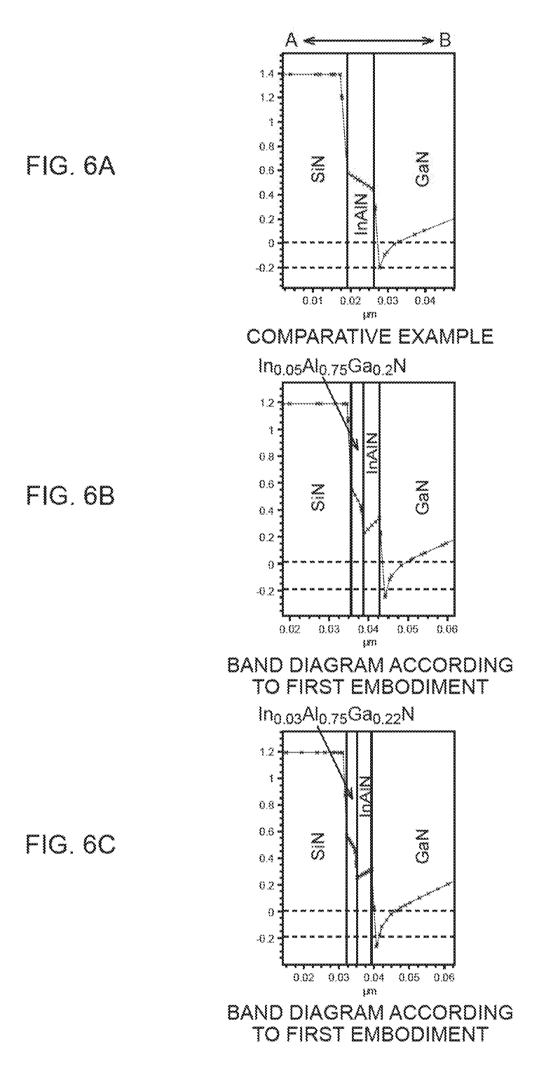

FIGS. 6A to 6C are characteristic diagrams illustrating a band structure in the InAlGaN/InAlN/GaN•HEMT fabricated using this embodiment on the basis of comparison with the comparative example. FIG. 6A indicates the comparative example, FIG. 6B indicates the case where the second electron supply layer is formed of In_{0.05}Al_{0.75}Ga_{0.2}N in this embodiment, and FIG. 6C indicates the case where the second electron supply layer is formed of In_{0.03}Al_{0.75}Ga_{0.22}N in this embodiment.

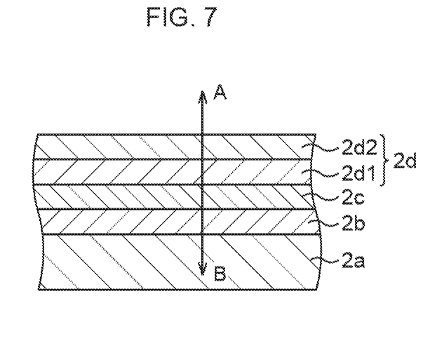

In FIGS. 6A to 6C, A-B is defined in a thickness direction of the compound semiconductor layer 2 as illustrated in FIG. 7. This also applies to the comparative example.

As illustrated in FIG. 7, the band structure discontinuously greatly changes at a boundary portion between the first electron supply layer and the second electron supply layer at which they are clearly different in In composition (having ΔEc) to improve the blocking performance. It has been confirmed that appropriate selection of the In composition ratio of the second electron supply layer and the film thicknesses of the first and second electron supply layers can sufficiently increase the two-dimensional electron gas concentration.

As has been described above, according to this embodiment, a highly reliable InAlGaN/InAlN/GaN•HEMT that suppresses occurrence of the leakage current and the current collapse and has high output performance, high efficiency and high frequency performance is realized.

### Second Embodiment

Hereinafter, an InAlGaN/InAlN/GaN•HEMT according to a second embodiment is described. This embodiment is different from the first embodiment in that the configuration of a compound semiconductor layer in the InAlGaN/InAlN/GaN•HEMT is slightly different from that in the first embodiment. Note that the constituent members and so on corresponding to those of the InAlGaN/InAlN/GaN•HEMT according to the first embodiment will be denoted by the same reference signs, and detailed descriptions thereof will be omitted.

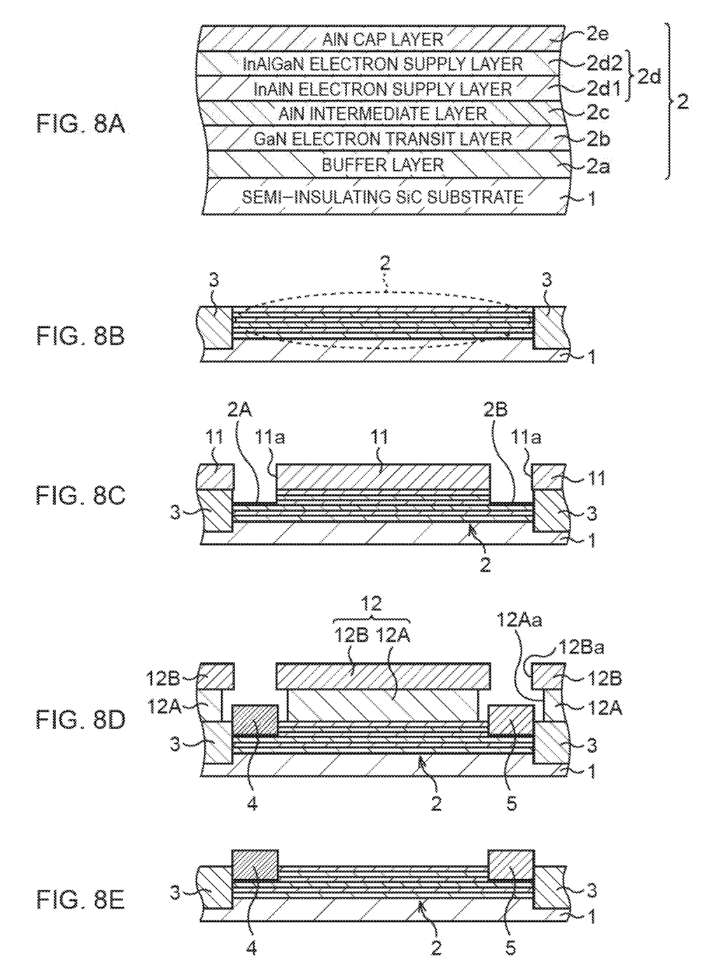

FIG. 8A to FIG. 10C are schematic cross-sectional views illustrating principal processes of the method of manufacturing the InAlGaN/InAlN/GaN•HEMT according to the second embodiment.

As illustrated in FIG. 8A, a compound semiconductor layer 2 being a layered structure of compound semiconductors is first formed on, for example, a semi-insulating SiC substrate 1 as a growth substrate.

As the growth substrate, a Si substrate, a sapphire substrate, a GaAs substrate, a GaN substrate, or the like may be used in place of the SiC substrate. Further, the conductivity of the substrate may be either semi-insulating or conductive.

The compound semiconductor layer 2 is composed of a buffer layer 2a, an electron transit layer 2b, an intermediate layer 2c, an electron supply layer 2d, and a cap layer 2e. The electron transit layer 2b includes GaN. The intermediate layer 2c includes, for example, AlN. The electron supply layer 2d is composed of a first electron supply layer 2d1 including InAlN, and a second electron supply layer 2d2 including InAlGaN formed on the first electron supply layer 2d1. The cap layer 2e includes AlN. In place of AlN, GaN can also be used. In the InAlGaN/InAlN/GaN•HEMT, a two-dimensional electron gas (2DEG) is generated in the vicinity of an interface of the electron transit layer 2b with the electron supply layer 2d (precisely, the intermediate layer 2c). Note that formation of the intermediate layer 2c may be omitted.

More specifically, each compound semiconductor below is grown by, for example, the MOVPE method on the SiC substrate 1 as in the first embodiment. The molecular beam epitaxy method or the like may be used in place of the MOVPE method.

On the SiC substrate 1, AlN, (intentionally undoped) —GaN, AlN, InAlN, InAlGaN, and AlN are deposited in sequence. The buffer layer 2a is formed of AlN or the like. The electron transit layer 2b is formed of i-GaN. The intermediate layer 2c is formed of AlN. The first electron supply layer 2d1 is formed of InAlN, for example, In_{0.17}AlN. The second electron supply layer 2d2 is formed of InAlGaN to be made relatively lower in In composition than InAlN of the first electron supply layer 2d1 by containing Ga, for example, an In composition of 5% or less. The cap layer 2e is formed of AlN.

The buffer layer 2a is formed into a film thickness of about 0.1 μm, the electron transit layer 2b is formed into a film thickness of about 3 μm, and the intermediate layer 2c is formed into a film thickness of about 1 nm. The first electron supply layer 2d1 is formed into a film thickness of about 5 nm and an In rate of 0.17, and the second electron supply layer 2d2 is formed into a film thickness of about 5 nm and an In rate of, for example, about 3% to 10% lower than that of the first electron supply layer 2d1. The cap layer 2e is formed into a film thickness of about 5 nm.

Subsequently, as illustrated in FIG. 8B, element isolation structures 3 are formed similarly to FIG. 1B of the first embodiment.

Subsequently, as illustrated in FIG. 8C, electrode trenches 2A, 2B are formed in the first electron supply layer 2d1, the second electron supply layer 2d2, and the cap layer 2e at planned electrode formation positions for a source electrode and a drain electrode in the surface of the compound semiconductor layer 2.

A resist is applied to the surface of the compound semiconductor layer 2 and processed by lithography. Thereby, a resist mask 11 having openings 11a exposing the planned electrode formation positions for the source electrode and the drain electrode in the surface of the compound semiconductor layer 2 is formed. Dry etching using the resist mask 11 is performed penetrating the cap layer 2e and the second electron supply layer 2d2 down to a middle of the first electron supply layer 2d1. This forms the electrode trenches 2A, 2B. For the dry etching, an inert gas such as Ar and a chlorine-based gas such as Cl₂ are used as an etching gas. Here, the dry etching may be performed penetrating the cap layer 2e, the second electron supply layer 2d2, and the first electron supply layer 2d1 down to a surface layer part of the electron transit layer 2b to thereby form the electrode trenches.

The resist mask 11 is removed by ashing using oxygen plasma or by wet treatment using a chemical.

Subsequently, as illustrated in FIGS. 8D, 8E, a source electrode 4 and a drain electrode 5 made by embedding lower parts of Ti/Al in the electrode trenches 2A, 2B are formed similarly to FIGS. 1D, 1E of the first embodiment.

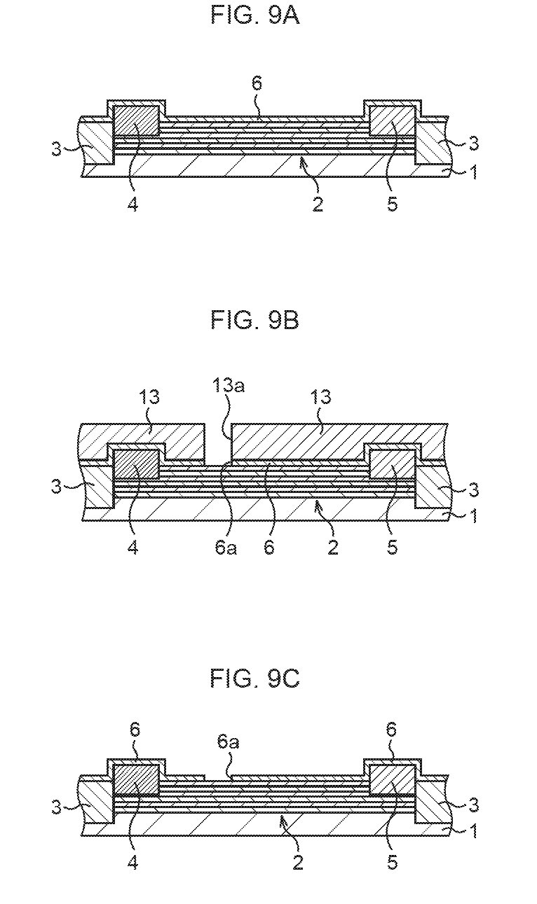

Subsequently, as illustrated in FIG. 9A, a protective insulating film 6 is formed similarly to FIG. 2A of the first embodiment.

Subsequently, as illustrated in FIG. 9B, a trench 6a is formed in the protective insulating film 6 similarly to FIG. 2B of the first embodiment.

Subsequently, as illustrated in FIG. 9C, a resist mask 13 is removed by ashing using oxygen plasma or by wet treatment using a chemical similarly to FIG. 2C of the first embodiment.

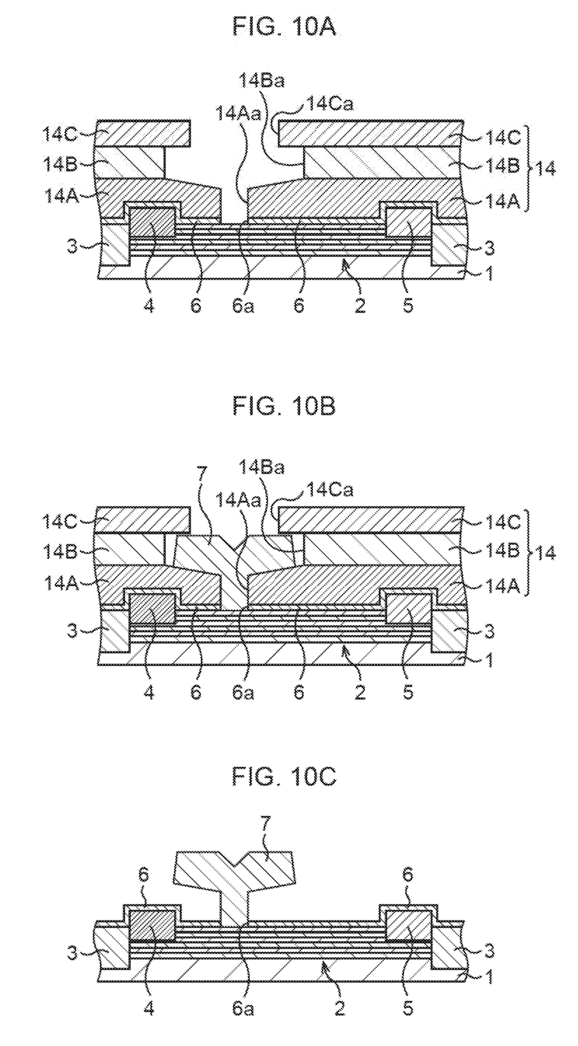

Subsequently, as illustrated in FIG. 10A, a resist mask 14 for formation of a gate is formed similarly to FIG. 3A of the first embodiment.

Subsequently, as illustrated in FIG. 10B, a gate electrode 7 is formed similarly to FIG. 3B of the first embodiment.

Subsequently, as illustrated in FIG. 10C, the resist mask 14 is removed similarly to FIG. 3C of the first embodiment.

Thereafter, through processes such as electrical connection and so on of the source electrode 4, the drain electrode 5, and the gate electrode 7, the InAlGaN/InAlN/GaN•HEMT according to this embodiment is formed.

In this embodiment, the electron supply layer 2d of the compound semiconductor layer 2 is formed in a two-layer structure having the first electron supply layer 2d1 of InAlN on the rear surface side (the electron transit layer 2b side) and the second electron supply layer 2d2 of InAlGaN on the front surface side. InAlN of the first electron supply layer 2d1 on the rear surface side can generate high spontaneous polarization electric charges with a relatively low In composition. Further, InAlN has a feature of being likely to cause crystal defects such as In condensation and the like as the film-forming technique. Therefore, it is impossible to achieve both a large current density by a high polarization density and a low gate leakage current. Furthermore, InAlGaN of the second electron supply layer 2d2 on the front surface side is lower in Al composition on the front surface than InAlN of the first electron supply layer 2d1, and therefor can reduce the current collapse caused by an Al oxide.

Further, in this embodiment, the cap layer 2e of AlN is formed on the second electron supply layer 2d2 of InAlGaN in the compound semiconductor layer 2. This configuration can achieve both a large current density by a high polarization density and a low gate leakage current. In addition, the uppermost surface of the compound semiconductor layer 2 is passivated by the cap layer 2e of AlN having a strong bond. The surface of the second electron supply layer 2d2 containing In is apt to be oxidized. Therefore, formation of the cap layer 2e of AlN covering the surface of the second electron supply layer 2d2 suppresses generation of a substance causing the current collapse such as AlO on the surface of the second electron supply layer 2d2, thereby reducing the occurrence of the current collapse due to an Al oxide.

Hereinafter, operations and effects exhibited by the InAlGaN/InAlN/GaN•HEMT according to this embodiment will be described based on comparison with a comparative example.

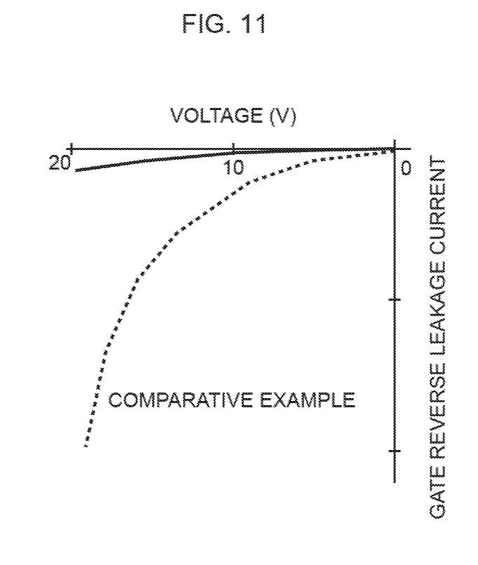

FIG. 11 is a characteristic diagram illustrating gate two-terminal reverse leakage characteristics in the InAlGaN/InAlN/GaN•HEMT fabricated using this embodiment on the basis of comparison with the comparative example. In the diagram, a solid line indicates this embodiment, and a broken line indicates the comparative example.

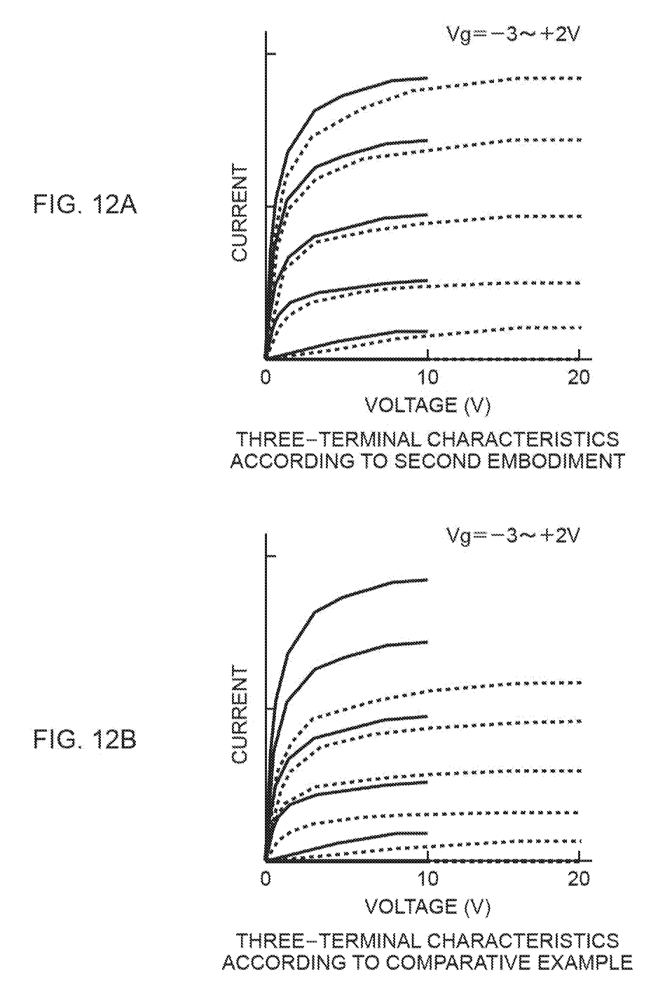

FIGS. 12A and 12B are characteristic diagrams illustrating three-terminal characteristics in the InAlGaN/InAlN/GaN•HEMT fabricated using this embodiment on the basis of comparison with the comparative example. FIG. 12A indicates this embodiment, and FIG. 12B indicates the comparative example. In the diagrams, solid lines indicate low-bias stress states, and broken lines indicate high-bias stress states.

The comparative example is a so-called InAlN/GaN•HEMT having an electron supply layer in a single-layer structure of InAlN.

It has been confirmed from the measurement results in FIG. 11 and FIGS. 12A and 12B that a large gate leakage current flows in the comparative example, whereas the gate leakage current is greatly reduced in this embodiment as compared with the comparative example. Further, an effect of reducing the current collapse by this embodiment has also been confirmed.

As has been described above, according to this embodiment, a highly reliable InAlGaN/InAlN/GaN•HEMT that suppresses occurrence of the leakage current and the current collapse and has high output performance, high efficiency and high frequency performance is realized.

### Third Embodiment

Hereinafter, an InAlGaN/InAlN/GaN•HEMT according to a third embodiment is described. This embodiment is different from the first embodiment in that the configuration of a compound semiconductor layer in the InAlGaN/InAlN/GaN•HEMT is slightly different from that in the first embodiment. Note that the constituent members and so on corresponding to those of the InAlGaN/InAlN/GaN•HEMT according to the first embodiment will be denoted by the same reference signs, and detailed descriptions thereof will be omitted.

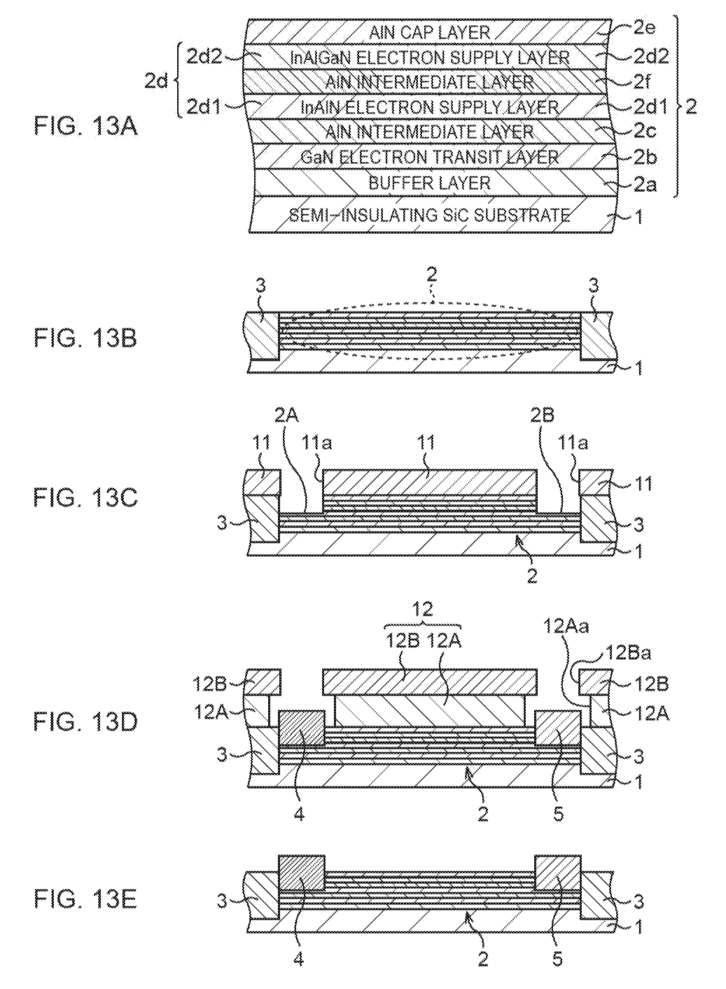

FIG. 13A to FIG. 15C are schematic cross-sectional views illustrating principal processes of the method of manufacturing the InAlGaN/InAlN/GaN•HEMT according to the third embodiment.

As illustrated in FIG. 13A, a compound semiconductor layer 2 being a layered structure of compound semiconductors is first formed on, for example, a semi-insulating SiC substrate 1 as a growth substrate.

As the growth substrate, a Si substrate, a sapphire substrate, a GaAs substrate, a GaN substrate, or the like may be used in place of the SiC substrate. Further, the conductivity of the substrate may be either semi-insulating or conductive.

The compound semiconductor layer 2 is composed of a buffer layer 2a, an electron transit layer 2b, an intermediate layer 2c, an electron supply layer 2d, an intermediate layer 2f, and a cap layer 2e. The electron transit layer 2b includes GaN. The intermediate layer 2c includes, for example, AlN. The electron supply layer 2d is composed of a first electron supply layer 2d1 including InAlN, and a second electron supply layer 2d2 including InAlGaN formed on the first electron supply layer 2d1. The intermediate layer 2f includes, for example, AlN and is formed between the first electron supply layer 2d1 and the second electron supply layer 2d2. The cap layer 2e includes AlN. In place of AlN, GaN can also be used. Besides, the cap layer does not have to be used. In the InAlGaN/InAlN/GaN•HEMT, a two-dimensional electron gas (2DEG) is generated in the vicinity of an interface of the electron transit layer 2b with the electron supply layer 2d (precisely, the intermediate layer 2c). Note that formation of the intermediate layer 2c may be omitted.

More specifically, each compound semiconductor below is grown by, for example, the MOVPE method on the SiC substrate 1 as in the first embodiment. The molecular beam epitaxy method or the like may be used in place of the MOVPE method.

On the SiC substrate 1, AlN, (intentionally undoped) —GaN, AlN, InAlN, InAlGaN, and AlN are deposited in sequence. The buffer layer 2a is formed of AlN or the like. The electron transit layer 2b is formed of i-GaN. The intermediate layer 2c is formed of AlN. The first electron supply layer 2d1 is formed of InAlN, for example, In_{0.17}AlN. The intermediate layer 2f is formed of AlN. The second electron supply layer 2d2 is formed of InAlGaN to be made relatively lower in In composition than InAlN of the first electron supply layer 2d1 by containing Ga, for example, an In composition of 5% or less. The cap layer 2e is formed of AlN.

The buffer layer 2a is formed into a film thickness of about 0.1 μm, the electron transit layer 2b is formed into a film thickness of about 3 μm, and the intermediate layer 2c is formed into a film thickness of about 1 nm. The first electron supply layer 2d1 is formed into a film thickness of about 5 nm and an In rate of 0.17, the intermediate layer 2f is formed into a film thickness of about 1 nm, and the second electron supply layer 2d2 is formed into a film thickness of about 5 nm and an In rate of, for example, about 3% to 10% lower than that of the first electron supply layer 2d1. The cap layer 2e is formed into a film thickness of about 2 nm.

Subsequently, as illustrated in FIG. 13B, element isolation structures 3 are formed similarly to FIG. 1B of the first embodiment.

Subsequently, as illustrated in FIG. 13C, electrode trenches 2A, 2B are formed in a part of the first electron supply layer 2d1 and in the intermediate layer 2f, the second electron supply layer 2d2, and the cap layer 2e at planned electrode formation positions for a source electrode and a drain electrode in the surface of the compound semiconductor layer 2.

A resist is applied to the surface of the compound semiconductor layer 2 and processed by lithography. Thereby, a resist mask 11 having openings 11a exposing the planned electrode formation positions for the source electrode and the drain electrode in the surface of the compound semiconductor layer 2 is formed. Dry etching using the resist mask 11 is performed penetrating the cap layer 2e, the second electron supply layer 2d2, and the intermediate layer 2f down to a middle of the first electron supply layer 2d1. This forms the electrode trenches 2A, 2B. For the dry etching, an inert gas such as Ar and a chlorine-based gas such as Cl₂ are used as an etching gas. Here, the dry etching may be performed penetrating the cap layer 2e, the second electron supply layer 2d2, the intermediate layer 2f, and the first electron supply layer 2d1 down to a surface layer part of the electron transit layer 2b to thereby form the electrode trenches.

The resist mask 11 is removed by ashing using oxygen plasma or by wet treatment using a chemical.

Subsequently, as illustrated in FIGS. 13D, 13E, a source electrode 4 and a drain electrode 5 made by embedding lower parts of Ti/Al in the electrode trenches 2A, 2B are formed similarly to FIGS. 1D, 1E of the first embodiment.

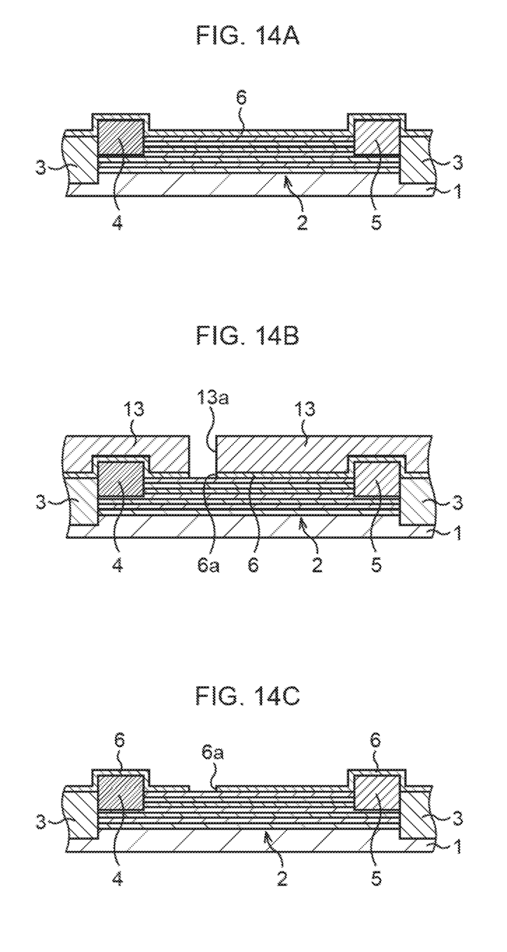

Subsequently, as illustrated in FIG. 14A, a protective insulating film 6 is formed similarly to FIG. 2A of the first embodiment.

Subsequently, as illustrated in FIG. 14B, a trench 6a is formed in the protective insulating film 6 similarly to FIG. 2B of the first embodiment.

Subsequently, as illustrated in FIG. 14C, a resist mask 13 is removed by ashing using oxygen plasma or by wet treatment using a chemical similarly to FIG. 2C of the first embodiment.

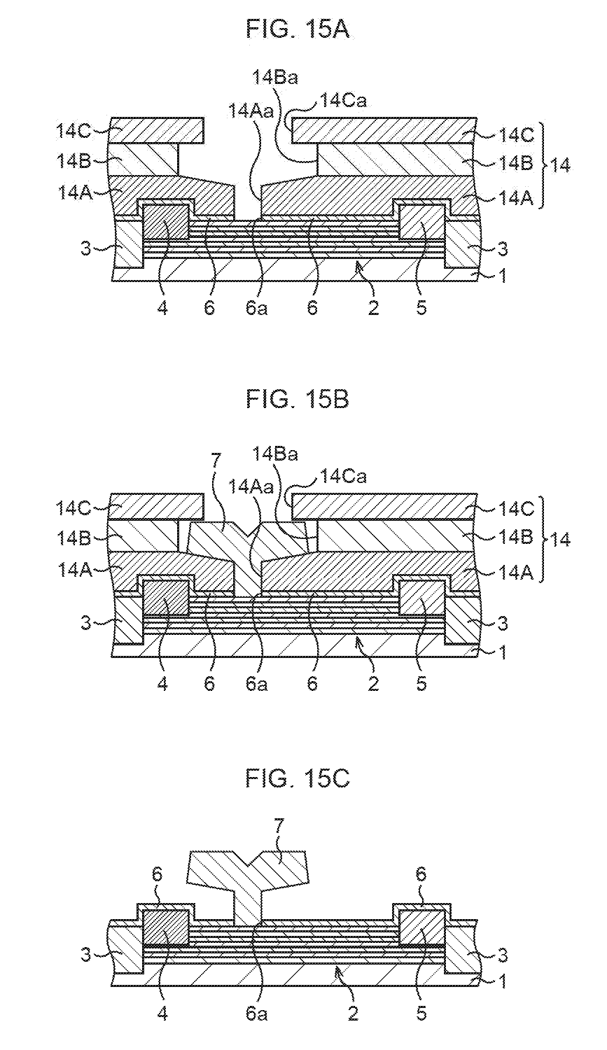

Subsequently, as illustrated in FIG. 15A, a resist mask 14 for formation of a gate is formed similarly to FIG. 3A of the first embodiment.

Subsequently, as illustrated in FIG. 15B, a gate electrode 7 is formed similarly to FIG. 3B of the first embodiment.

Subsequently, as illustrated in FIG. 15C, the resist mask 14 is removed similarly to FIG. 3C of the first embodiment.

Thereafter, through processes such as electrical connection and so on of the source electrode 4, the drain electrode 5, and the gate electrode 7, the InAlGaN/InAlN/GaN•HEMT according to this embodiment is formed.

In this embodiment, the electron supply layer 2d of the compound semiconductor layer 2 is formed in a two-layer structure having the first electron supply layer 2d1 of InAlN on the rear surface side (the electron transit layer 2b side) and the second electron supply layer 2d2 of InAlGaN on the front surface side. InAlN of the first electron supply layer 2d1 on the rear surface side can generate high spontaneous polarization electric charges with a relatively low In composition. Further, InAlN has a feature of being likely to cause crystal defects such as In condensation and the like as the film-forming technique. Therefore, it is impossible to achieve both a large current density by a high polarization density and a low gate leakage current. Furthermore, InAlGaN of the second electron supply layer 2d2 on the front surface side is lower in Al composition on the front surface than InAlN of the first electron supply layer 2d1, and therefor can reduce the current collapse caused by an Al oxide.

Further, in this embodiment, the cap layer 2e of AlN is formed on the second electron supply layer 2d2 of InAlGaN in the compound semiconductor layer 2. This configuration can achieve both a large current density by a high polarization density and a low gate leakage current. In addition, the uppermost surface of the compound semiconductor layer 2 is passivated by the cap layer 2e of AlN having a strong bond. The surface of the second electron supply layer 2d2 containing In is apt to be oxidized. Therefore, formation of the cap layer 2e of AlN covering the surface of the second electron supply layer 2d2 suppresses generation of a substance causing the current collapse such as AlO on the surface of the second electron supply layer 2d2, thereby reducing the occurrence of the current collapse due to an Al oxide.

Furthermore, in this embodiment, the intermediate layer 2f formed of AlN is inserted at a boundary portion between the first electron supply layer 2d1 and the second electron supply layer 2d2 constituting the electron supply layer 2 in order to form a clear heterojunction interface at the boundary portion. This configuration can improve the crystal quality of InAlN itself of the first electron supply layer 2d1 and InAlGaN itself of the second electron supply layer 2d2. This configuration also greatly contributes to improvement in quality of the hetero-interface of InAlGaN/InAlN. As an advantage in terms of electric property, improvement in spontaneous polarization generation efficiency due to the improvement in crystal quality enables realization of more current densities by the same crystal structure. Further, the improvement in crystal quality can suppress generation of an electron trap level to reduce the current collapse.

Hereinafter, operations and effects exhibited by the InAlGaN/InAlN/GaN•HEMT according to this embodiment will be described based on comparison with a comparative example.

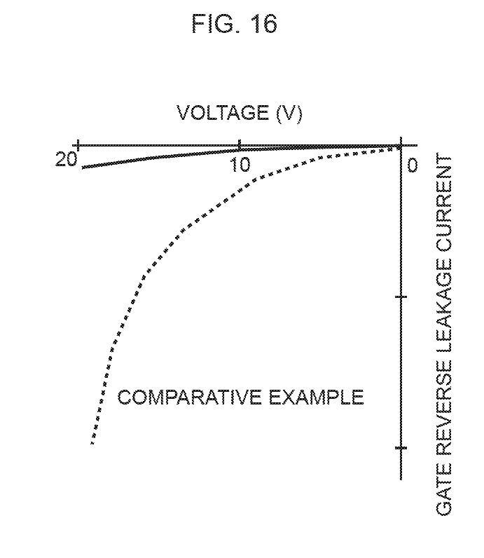

FIG. 16 is a characteristic diagram illustrating gate two-terminal reverse leakage characteristics in the InAlGaN/InAlN/GaN•HEMT fabricated using this embodiment on the basis of comparison with the comparative example. In the diagram, a solid line indicates this embodiment, and a broken line indicates the comparative example.

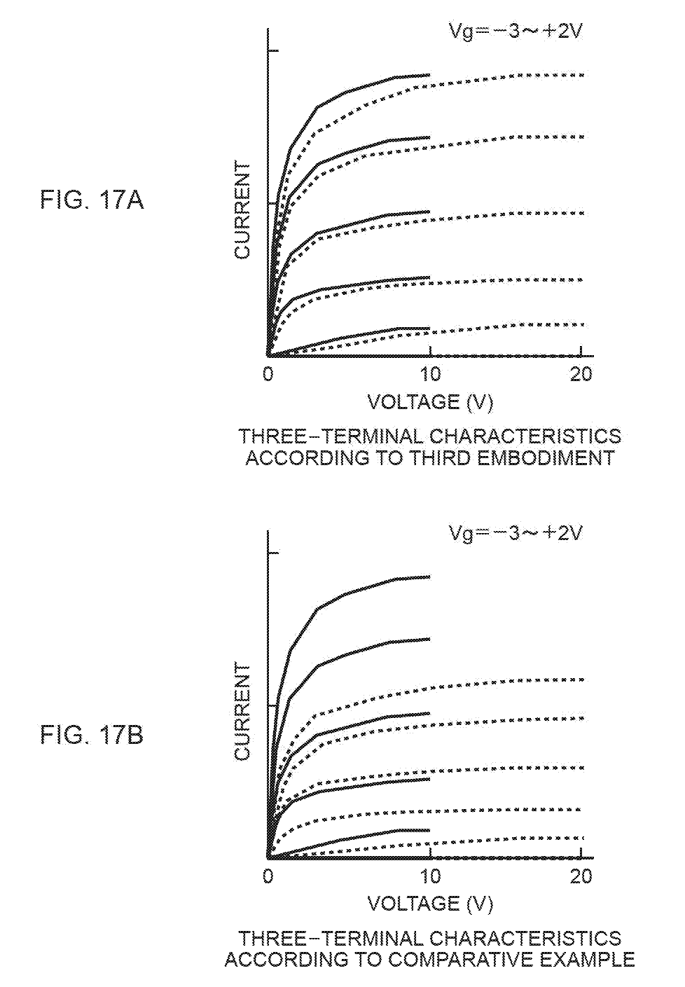

FIGS. 17A and 17B are characteristic diagrams illustrating three-terminal characteristics in the InAlGaN/InAlN/GaN•HEMT fabricated using this embodiment on the basis of comparison with the comparative example. FIG. 17A indicates this embodiment, and FIG. 17B indicates the comparative example. In the diagrams, solid lines indicate low-bias stress states, and broken lines indicate high-bias stress states.

The comparative example is a so-called InAlN/GaN•HEMT having an electron supply layer in a single-layer structure of InAlN.

It has been confirmed from the measurement results in FIG. 16 and FIGS. 17A and 17B that a large gate leakage current flows in the comparative example, whereas the gate leakage current is greatly reduced in this embodiment as compared with the comparative example. Further, an effect of reducing the current collapse by this embodiment has also been confirmed.

As has been described above, according to this embodiment, a highly reliable InAlGaN/InAlN/GaN•HEMT that suppresses occurrence of the leakage current and the current collapse and has high output performance, high efficiency and high frequency performance is realized.

### Fourth Embodiment

Hereinafter, an InAlGaN/InAlN/GaN•HEMT according to a fourth embodiment is described. This embodiment is different from the first embodiment in that the configurations of the periphery of a source electrode and the periphery of a drain electrode of a compound semiconductor layer in the InAlGaN/InAlN/GaN•HEMT are slightly different from those in the first embodiment. Note that the constituent members and so on corresponding to those of the InAlGaN/InAlN/GaN•HEMT according to the first embodiment will be denoted by the same reference signs, and detailed descriptions thereof will be omitted.

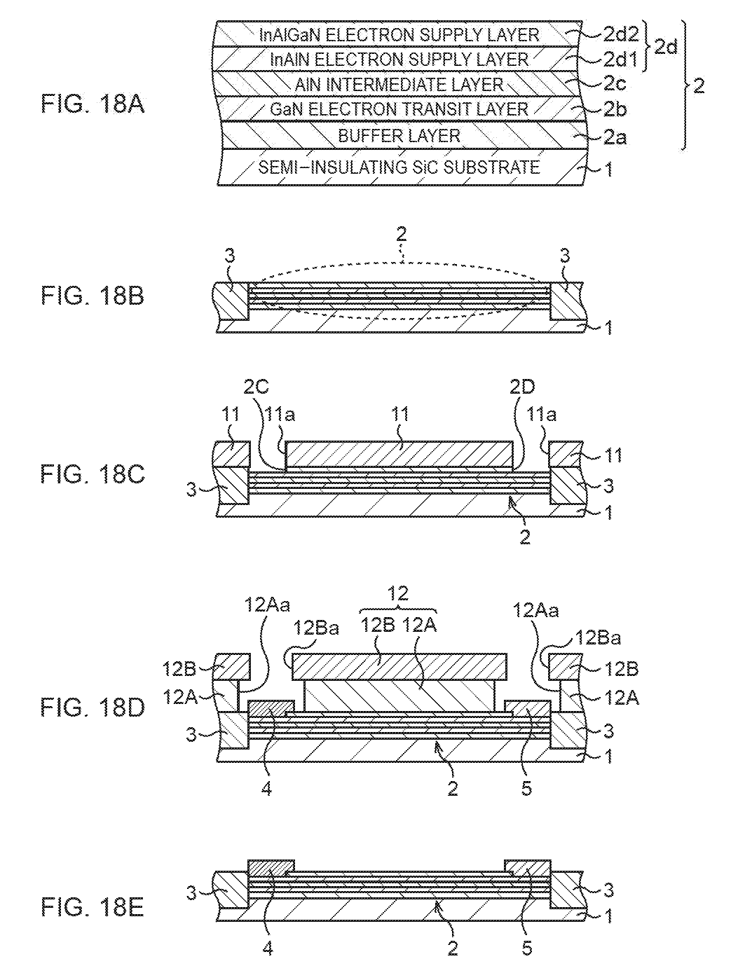

FIG. 18A to FIG. 20C are schematic cross-sectional views illustrating principal processes of the method of manufacturing the InAlGaN/InAlN/GaN•HEMT according to the fourth embodiment.

As illustrated in FIG. 18A, a compound semiconductor layer 2 is first formed similarly to FIG. 1A of the first embodiment. Here, a cap layer 2e of AlN may be formed on a second electron supply layer 2d2 as in the first embodiment. Besides, an intermediate layer 2f of AlN may be formed between a first electron supply layer 2d1 and the second electron supply layer 2d2 as in the third embodiment.

Subsequently, as illustrated in FIG. 18B, element isolation structures 3 are formed similarly to FIG. 1B of the first embodiment.

Subsequently, as illustrated in FIG. 18C, electrode trenches 2C, 2D are formed in the second electron supply layer 2d2 and the cap layer 2e at planned electrode formation positions for the source electrode and the drain electrode in the surface of the compound semiconductor layer 2.

A resist is applied to the surface of the compound semiconductor layer 2 and processed by lithography. Thereby, a resist mask 11 having openings 11a exposing the planned electrode formation positions for the source electrode and the drain electrode in the surface of the compound semiconductor layer 2 is formed. Dry etching using the resist mask 11 is performed on the second electron supply layer 2d2. This penetrates the second electron supply layer 2d2 to form the electrode trenches 2C, 2D exposing the surface of the first electron supply layer 2d1. For the dry etching, an inert gas such as Ar and a chlorine-based gas such as Cl₂ are used as an etching gas.

The resist mask 11 is removed by ashing using oxygen plasma or by wet treatment using a chemical.

Subsequently, as illustrated in FIGS. 18D, 18E, a source electrode 4 and a drain electrode 5 are formed.

As an electrode material, for example, Ti/Al is used. For formation of the electrodes, for example, an eaves-structure two-layer resist mask 12 suitable for a vapor deposition method and a lift-off method is formed. The resist mask 12 is composed of a lower layer resist 12A having openings 12Aa and an upper layer resist 12Ba having openings 12Ba. The electrode trench 2C and a part of the surface of the first electron supply layer 2d1 continuous thereto are exposed from one of the openings 12Ba, and the electrode trench 2D and a part of the surface of the first electron supply layer 2d1 continuous thereto are exposed from the other of the openings 12Ba. Using this resist mask 12, Ti/Al is deposited. The thickness of Ti is set to about 20 nm, and the thickness of Al is set to about 200 nm. By the lift-off method, the resist mask 12 and Ti/Al deposited thereon (illustration thereof is omitted in FIG. 18D) are removed. Thereafter, the SiC substrate 1 is heat treated at about 550° C., for example, in a nitrogen atmosphere, and remaining Ti/Al is brought into ohmic contact with the first electron supply layer 2d1. Thereby, the source electrode 4 and the drain electrode 5 are formed which are made by embedding lower parts of Ti/Al are embedded in the electrode trenches 2C, 2D and have upper ends running over the surface of the second electron supply layer 2d2.

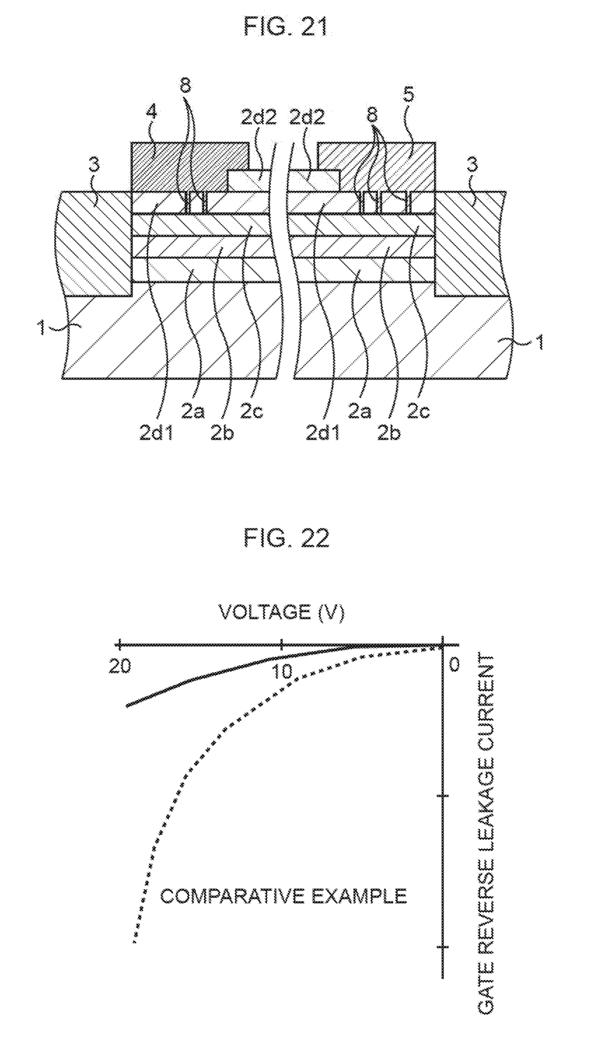

In this embodiment, after the dry etching is performed in FIG. 18C, acid treatment may be performed on exposed portions from the openings 11a of the first electron supply layer 2d1 with the resist mask 11 being formed. This acid treatment opens In condensation points in the surface of the first electron supply layer 2d1 as illustrated in FIG. 21 to thereby form fine pits (pin holes) 8 in the first electron supply layer 2d1 in the film thickness direction thereof. By forming the source electrode 4 and the drain electrode 5 and performing heat treatment, the material of the source electrode 4 and the drain electrode 5 comes into contact with a portion below the second electron supply layer 2d2, here, the intermediate layer 2c via the pits 8, resulting in reliable ohmic contact.

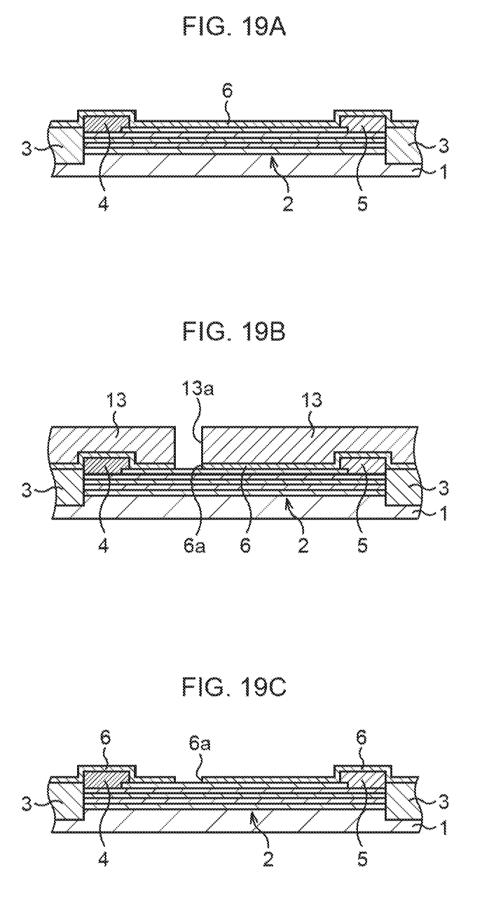

Subsequently, as illustrated in FIG. 19A, a protective insulating film 6 is formed similarly to FIG. 2A of the first embodiment.

Subsequently, as illustrated in FIG. 19B, a trench 6a is formed in the protective insulating film 6 similarly to FIG. 2B of the first embodiment.

Subsequently, as illustrated in FIG. 19C, a resist mask 13 is removed by ashing using oxygen plasma or by wet treatment using a chemical similarly to FIG. 2C of the first embodiment.

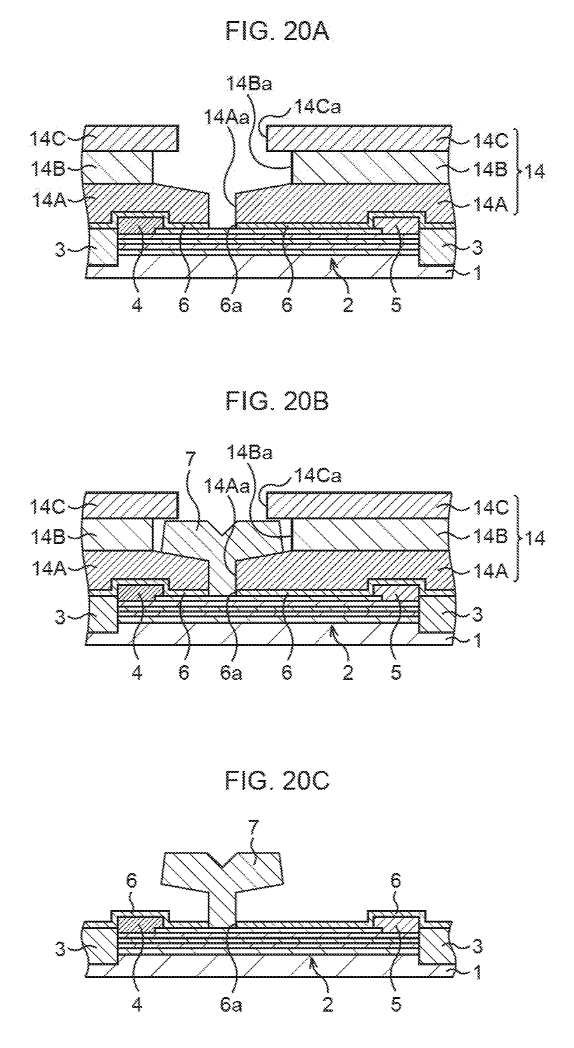

Subsequently, as illustrated in FIG. 20A, a resist mask 14 for formation of a gate is formed similarly to FIG. 3A of the first embodiment.

Subsequently, as illustrated in FIG. 20B, a gate electrode 7 is formed similarly to FIG. 3B of the first embodiment.

Subsequently, as illustrated in FIG. 20C, the resist mask 14 is removed similarly to FIG. 3C of the first embodiment.

Thereafter, through processes such as electrical connection and so on of the source electrode 4, the drain electrode 5, and the gate electrode 7, the InAlGaN/InAlN/GaN•HEMT according to this embodiment is formed.

In this embodiment, the electron supply layer 2d of the compound semiconductor layer 2 is formed in a two-layer structure having the first electron supply layer 2d1 of InAlN on the rear surface side (the electron transit layer 2b side) and the second electron supply layer 2d2 of InAlGaN on the front surface side. InAlN of the first electron supply layer 2d1 on the rear surface side can generate high spontaneous polarization electric charges with a relatively low In composition. Further, InAlN has a feature of being likely to cause crystal defects such as In condensation and the like as the film-forming technique. Therefore, it is impossible to achieve both a large current density by a high polarization density and a low gate leakage current. Furthermore, InAlGaN of the second electron supply layer 2d2 on the front surface side is lower in Al composition on the front surface than InAlN of the first electron supply layer 2d1, and therefor can reduce the current collapse caused by an Al oxide.

As described above, the In condensation point is apt to be formed in InAlN. The condensation point existing in a gate electrode region causes gate leakage, but the In condensation point existing in the region for forming the ohmic electrode of InAlN contributes to improvement in ohmic property. In this embodiment, the electrode trenches 2C, 2D are formed in the second electron supply layer 2d2 of InAlGaN to bring the source electrode 4 and the drain electrode 5 being ohmic electrodes into contact with InAlN of the first electron supply layer 2d1 having many In condensation points. In this configuration, excellent ohmic contact is formed at a portion in contact with the In condensation point of InAlN. Further, the source electrode 4 and the drain electrode 5 being the ohmic electrodes are formed such that their upper ends run over the surface of the second electron supply layer 2d2. This configuration prevents a decrease in 2DEG concentration at ends of the source electrode 4 and the drain electrode 5, and enables formation of reliable ohmic electrodes with low on-resistance and no electric field concentration.

Hereinafter, operations and effects exhibited by the InAlGaN/InAlN/GaN•HEMT according to this embodiment will be described based on comparison with a comparative example.

FIG. 22 is a characteristic diagram illustrating gate two-terminal reverse leakage characteristics in the InAlGaN/InAlN/GaN•HEMT fabricated using this embodiment on the basis of comparison with the comparative example. In the diagram, a solid line indicates this embodiment, and a broken line indicates the comparative example.

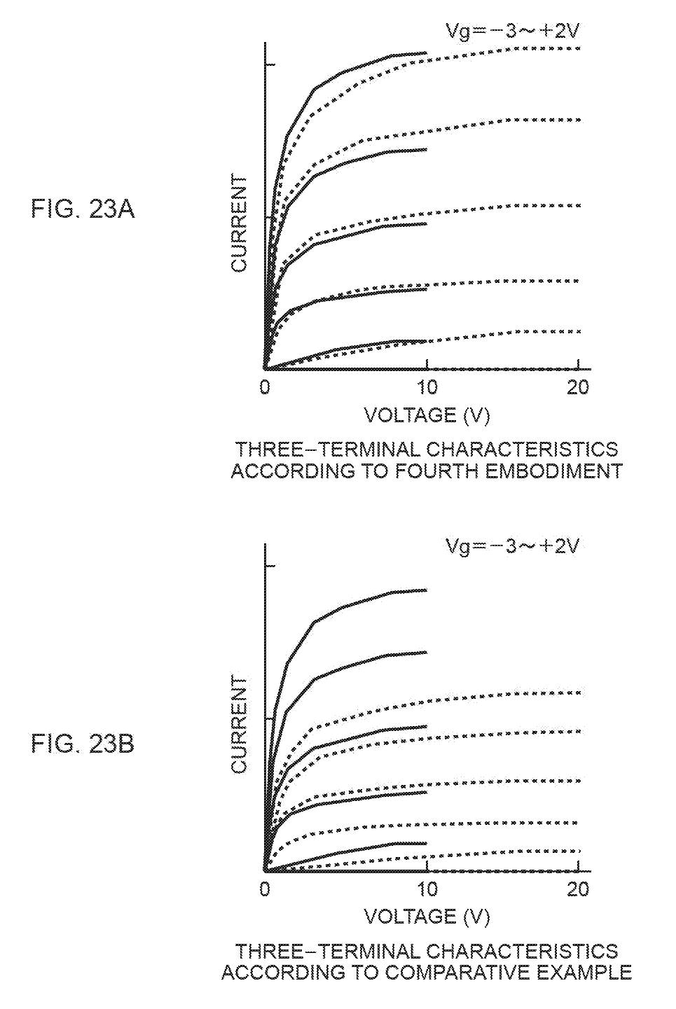

FIGS. 23A and 23B are characteristic diagrams illustrating three-terminal characteristics in the InAlGaN/InAlN/GaN•HEMT fabricated using this embodiment on the basis of comparison with the comparative example. FIG. 23A indicates this embodiment, and FIG. 23B indicates the comparative example. In the diagrams, solid lines indicate low-bias stress states, and broken lines indicate high-bias stress states.

The comparative example is a so-called InAlN/GaN•HEMT having an electron supply layer in a single-layer structure of InAlN.

It has been confirmed from the measurement results in FIG. 22 and FIGS. 23A and 23B that a large gate leakage current flows in the comparative example, whereas the gate leakage current is greatly reduced in this embodiment as compared with the comparative example. Further, an effect of reducing the current collapse by this embodiment has also been confirmed.

As has been described above, according to this embodiment, a highly reliable InAlGaN/InAlN/GaN•HEMT that suppresses occurrence of the leakage current and the current collapse and has high output performance, high efficiency and high frequency performance is realized.

Note that though the Schottky-type InAlGaN/InAlN/GaN•HEMTs in which the gate electrode 7 is in contact with the surface of the compound semiconductor layer 2 have been described in the first to fourth embodiments, the present invention is also applicable to a MIS-type InAlGaN/InAlN/GaN•HEMT. In the case of the MIS-type InAlGaN/InAlN/GaN•HEMT, for example, the protective insulating film 6 is used as a gate insulating film. The gate electrode 7 only needs to be formed on the compound semiconductor layer 2 via the protective insulating film 6 without forming the trench 6a in the protective insulating film 6. Besides, an insulating film of Al₂O₃, AlN, or HfO₂ can be used as the protective insulating film 6.

### Fifth Embodiment

This embodiment discloses a power supply device including one kind of InAlGaN/InAlN/GaN•HEMT selected from among the first to fourth embodiments.

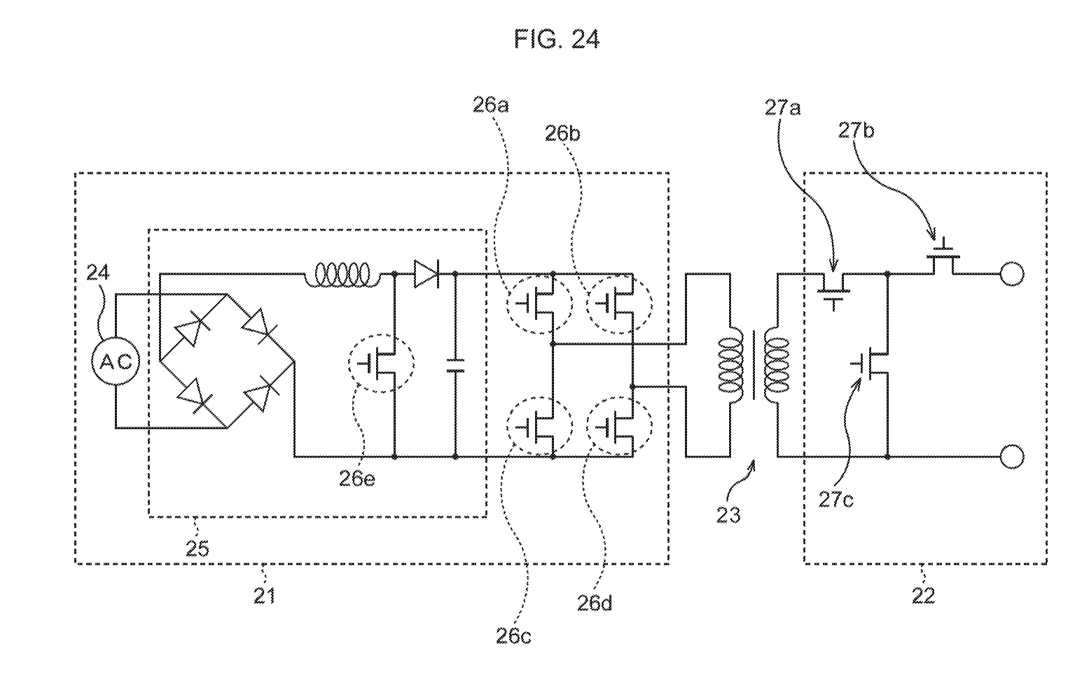

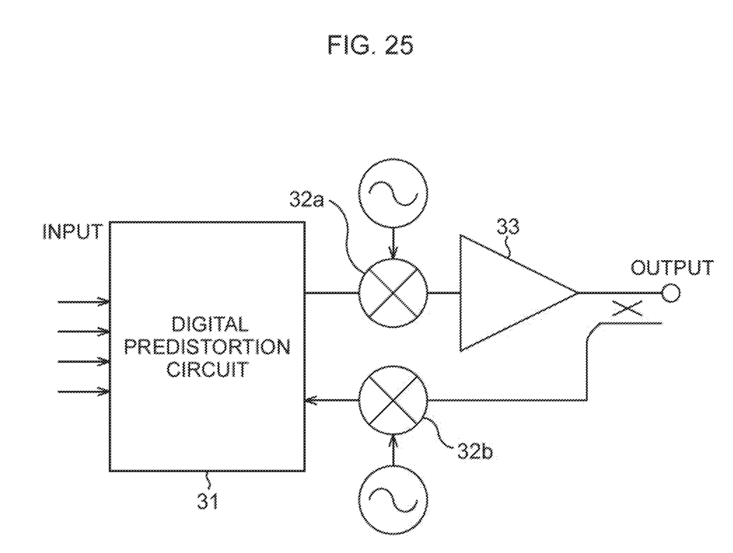

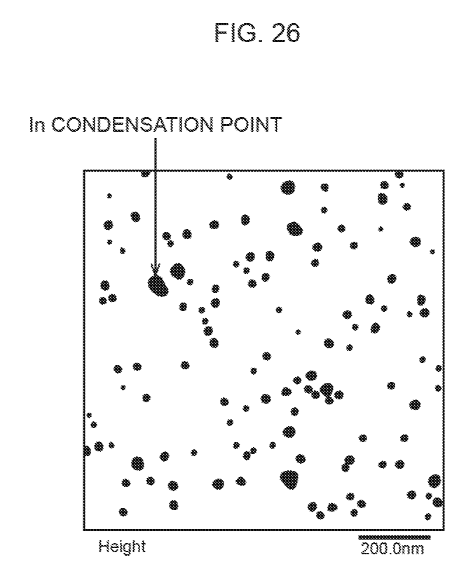

FIG. 24 is a connection diagram illustrating a schematic configuration of the power supply device according to a fifth embodiment.

The power supply device according to this embodiment is composed a high-voltage primary-side circuit 21, a low-voltage secondary-side circuit 22, and a transformer 23 disposed between the primary-side circuit 21 and the secondary-side circuit 22.

The primary-side circuit 21 includes an AC power supply 24, a so-called bridge rectifying circuit 25, and a plurality of (four here) switching elements 26a, 26b, 26c, 26d. Further, the bridge rectifying circuit 25 has a switching element 26e.

The secondary-side circuit 22 is composed of a plurality of (three here) switching elements 27a, 27b, 27c.

In this embodiment, the switching elements 26a, 26b, 26c, 26d, 26e of the primary-side circuit 21 are each one kind of the InAlGaN/InAlN/GaN•HEMT selected from among the first to fourth embodiments. On the other hand, the switching elements 27a, 27b, 27c of the secondary-side circuit 22 are each an ordinary MIS•FET using silicon.

According to this embodiment, a highly reliable InAlGaN/InAlN/GaN•HEMT that suppresses occurrence of the leakage current and the current collapse and has high output performance, high efficiency and high frequency performance is applied to a high-voltage circuit. This realizes a highly reliable large-power supply circuit.

### Sixth Embodiment

This embodiment discloses a high-frequency amplifier including one kind of InAlGaN/InAlN/GaN•HEMT selected from among the first to fourth embodiments.

FIG. 25 is a connection diagram illustrating a schematic configuration of the high-frequency amplifier according to a sixth embodiment.

The high-frequency amplifier according to this embodiment is composed of a digital predistortion circuit 31, mixers 32a, 32b, and a power amplifier 33.

The digital predistortion circuit 31 compensates nonlinear distortion of an input signal. The mixer 32a mixes the input signal whose nonlinear distortion has been compensated and an AC signal. The power amplifier 33 amplifies the input signal mixed with the AC signal, and has one kind of InAlGaN/InAlN/GaN•HEMT selected from among the first to fourth embodiments. Note that in FIG. 25, for example, by changing the switches, an output-side signal can be mixed with the AC signal by the mixer 32b, and the resultant signal can be sent out to the digital predistortion circuit 31.

In this embodiment, a highly reliable InAlGaN/InAlN/GaN•HEMT that suppresses occurrence of the leakage current and the current collapse and has high output performance, high efficiency and high frequency performance is applied to a high-frequency amplifier. This realizes a highly reliable high-withstand-voltage high-frequency amplifier.

According to the above various aspects, a highly reliable compound semiconductor device that suppresses occurrence of the leakage current and the current collapse and has high output performance, high efficiency and high frequency performance can be realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
a compound semiconductor layer comprising an electron transit layer and an electron supply layer above the electron transit layer,
the electron supply layer comprising:
a first layer including InAlN; and
a second layer including InAlGaN formed above the first layer.

2. The compound semiconductor device according to claim 1,
wherein the compound semiconductor layer further comprises a cap layer including AlN formed above the electron supply layer.

3. The compound semiconductor device according to claim 1,
wherein the compound semiconductor layer further comprises a first intermediate layer including AlN formed between the electron transit layer and the electron supply layer.

4. The compound semiconductor device according to claim 1,
wherein the compound semiconductor layer further comprises a second intermediate layer including AlN formed between the first layer and the second layer.

5. The compound semiconductor device according to claim 1, further comprising:
an electrode in ohmic contact with the first layer, on the compound semiconductor layer.

6. The compound semiconductor device according to claim 5,
wherein the second layer is formed with a trench, and
wherein the electrode is formed to be embedded in the trench.

7. The compound semiconductor device according to claim 5,
wherein the first layer is formed with a pit communicating with a portion under the first layer, and
wherein the electrode is in ohmic contact with the portion under the first layer via the pit.

8. A method of manufacturing a compound semiconductor device, the method comprising:
when forming a compound semiconductor layer,
forming an electron transit layer; and
forming an electron supply layer above the electron transit layer,
the electron supply layer comprising:
a first layer including InAlN; and
a second layer including InAlGaN formed above the first layer.

9. The method of manufacturing a compound semiconductor device according to claim 8, further comprising:
forming a cap layer including AlN above the electron supply layer.

10. The method of manufacturing a compound semiconductor device according to claim 8, further comprising:
forming a first intermediate layer including AlN between the electron transit layer and the electron supply layer.

11. The method of manufacturing a compound semiconductor device according to claim 8, further comprising:
forming a second intermediate layer including AlN between the first layer and the second layer.

12. The method of manufacturing a compound semiconductor device according to claim 8, further comprising:
forming an electrode in ohmic contact with the first layer, on the compound semiconductor layer.

13. The method of manufacturing a compound semiconductor device according to claim 12, further comprising:
forming a trench in the second layer,
wherein the electrode is formed to be embedded in the trench.

14. The method of manufacturing a compound semiconductor device according to claim 12, further comprising:
forming a pit communicating with a portion under the first layer, in the first layer,
wherein the electrode is in ohmic contact with the portion under the first layer via the pit.

15. The method of manufacturing a compound semiconductor device according to claim 14,
wherein the pit is formed at an In condensation point of the first layer by performing acid treatment on a surface of the first layer.

16. A power supply circuit comprising a transformer, and a high-voltage circuit and a low-voltage circuit across the transformer,
the high-voltage circuit comprising a transistor,
the transistor comprising a compound semiconductor layer comprising an electron transit layer and an electron supply layer above the electron transit layer,
the electron supply layer comprising:
a first layer including InAlN; and
a second layer including InAlGaN formed above the first layer.

17. A high-frequency amplifier that amplifies a high-frequency voltage inputted thereto and outputs a resultant high-frequency voltage, the high-frequency amplifier comprising:
a transistor, the transistor comprising:
a compound semiconductor layer comprising an electron transit layer and an electron supply layer above the electron transit layer,
the electron supply layer comprising:
a first layer including InAlN; and
a second layer including InAlGaN formed above the first layer.
